(19) United States
(12) Patent Application Publication
(10) Pub. No.: US 2012/0112330 A1
(43) Pub. Date: May 10, 2012

(54) SEMICONDUCTOR DEVICE

(75) Inventors: Ping-Chia Liao, New Taipei City (TW); Chin-Yung Chen, Daxi Township (TW); Chun-Chieh Yang, Taichung City (TW)

(73) Assignee: RAYDIUM SEMICONDUCTOR CORPORATION, Hsinchu (TW)

(21) Appl. No.: 13/195,454

(22) Filed: Aug. 1, 2011

(30) Foreign Application Priority Data
Nov. 10, 2010 (TW) 99138700

(51) Int. Cl. H01L 23/495

(52) U.S. Cl. 257/668; 257/E23.052

(57) ABSTRACT

A semiconductor device, such as a semiconductor device of chip on film package, is provided. The semiconductor device includes at least an integrated circuit formed on a film base, each integrated circuit includes a chip and a plurality of leads formed interior to a boundary of a predetermined range, each lead is formed with a predetermined distance from the boundary. While the integrated circuit is punched from the film base along the boundary, conductive residue of leads left on the puncher is therefore reduced or avoided.

This application claims the benefit of Taiwan Patent Application serial No. 99138700, filed Nov. 10, 2010, the subject matter of which is incorporated herein by reference.

### FIELD OF THE INVENTION

The present invention relates to a semiconductor device, and more particularly, to a semiconductor device of chip on film package constraining lead extension to reduce or avoid lead residue left on puncher.

### BACKGROUND OF THE INVENTION

Semiconductor devices, such as semiconductor integrated circuits of various packages, have become the most important hardware foundations of modern information society.

Among various kinds of semiconductor devices, one kind of semiconductor devices has integrated circuit(s) formed on a flexible base; for example, semiconductor devices of COF (chip on film or chip on flex) package or TCP (tap carrier package) have multiple chips packaged on flexible film bases or tap bases to form multiple integrated circuits. Corresponding to each chip in each integrated circuit, leads are formed on conductive layer(s) of the base; when the chip is packaged on the base, the chip is coupled to the leads so the chip can communicate with other circuits via the leads. This kind of semiconductor devices has been broadly adopted; for example, driving integrated circuits (drivers) for liquid crystal display panels are formed on flexible bases.

### SUMMARY OF THE INVENTION

For semiconductor devices of flexible base, because multiple integrated circuits are formed on a same base, each of the integrated circuits needs to be punched from the base by a puncher. The puncher punches according to a cut line corresponding to each integrated circuit; for known semiconductor devices of flexible base, leads of each integrated circuit extend across the corresponding cut line. However, by analysis of the invention, it is recognized that leads across the cut line will cause conductive residue left on the puncher while punched, and the conductive residue causes erroneous short circuit of different leads to impact normal operation of integrated circuit and to lower yield of semiconductor devices.

To address the issues, one objective of the invention is to provide a semiconductor device including a base and one or multiple integrated circuits. Each integrated circuit is formed on the base and includes a chip and a plurality of conductive leads set interior to a predetermined range which has a boundary, i.e., a cut line. In each integrated circuit, each lead extends from the chip toward the boundary to a bonding area inside the predetermined range with a predetermined distance separated away from the boundary.

In an embodiment of the invention, each integrated circuit further corresponds to a plurality of extension segments and a plurality of external segments. Each of the external segments is set exterior to the predetermined range, and is coupled to one of the leads through one of the extension leads extending across the boundary. A width of each extension segment is less than a width of each lead.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) illustrates a semiconductor device of a flexible base;

FIG. 2 and FIG. 3 illustrate different embodiments according to the invention; and

FIG. 4 compares embodiments of FIG. 1 to FIG. 3.

### DETAILED DESCRIPTION OF PREFERRED EMBODIMENTS

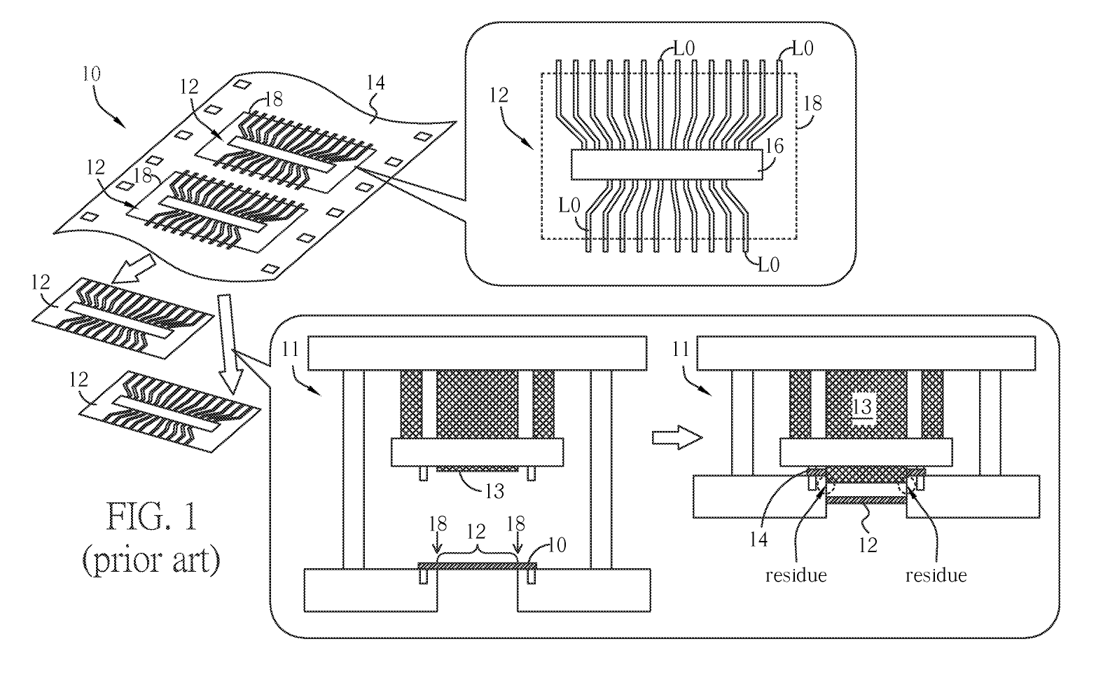

Please refer to FIG. 1 illustrating a conventional semiconductor device 10 of chip on film package. The semiconductor device 10 includes multiple integrated circuits 12 formed on a flexible base 14; each integrated circuit 12 has a range defined by a corresponding cut line 18. Each integrated circuit 12 includes a chip 16 and a plurality of leads L0, each lead L0 is formed on a conductive layer (e.g., a conductive copper layer) and extends outwards, so the chip 16 can be coupled to other external circuit (not shown) through the leads L0. As shown in FIG. 1, in each integrated circuit 12 of the conventional semiconductor device 10, the leads L0 extend across the cut line 18 to reach outside of the cut line 18.

When each integrated circuit 12 is separated from the base 14, the semiconductor device 10 will be placed on a puncher 11; a punch head 13 of the puncher 11 cuts each integrated circuit 12 off the base 14 along the cut line 18. As shown in FIG. 1, however, because the leads L0 extend outside the cut line 18, the punch head 13 also cuts the leads L0 while punching, and conductive residue of the leads L0 will be left on the puncher 11. The conductive residue contaminates the integrated circuit(s) 12; when the residue fills between two leads, the two leads supposed to be isolated will be erroneously shorted, and then the integrated circuit 12 can not function correctly.

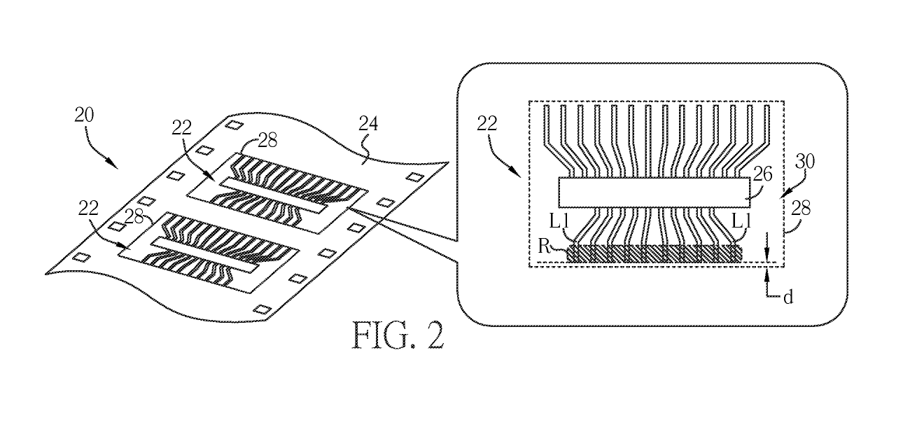

To address issues of residual remains of the semiconductor device 10, the invention provides a semiconductor with a better lead design. Please refer to FIG. 2 illustrating a semiconductor device 20 according to an embodiment of the invention. The semiconductor device 20 can be a semiconductor device of chip on film package or tap carrier package. The semiconductor device 20 has multiple integrated circuits 22 formed on a base 24; the base 24 can be a flexible base, such as a film base or a tape base.

Each integrated circuit 22 of the semiconductor device 20 includes a chip 26 and multiple leads L1. The chip 26 is set inside a predetermined range 30 of the base 24; the predetermined range 30 is surrounded by a boundary 28, the boundary 28 can be a cut line of punch. Each lead L1 is set inside the predetermined range 30; each lead L1 is coupled to the chip 26 (e.g., to a pad of the chip 26), and extends from the chip 26 toward the boundary 28, so the chip 26 can be coupled to other external circuit(s) (e.g., other chip(s), integrated circuit(s) and/or circuit board(s), not shown) for exchanging signal/data and draining operation power.

However, as shown in FIG. 2 of the invention, each lead L1 is separated from the boundary 28 by a predetermined distance d and therefore does not reach the boundary 28. Each lead L1 can be formed on a conductive layer (e.g., a copper conductive layer) of the base 24, and extends outwards from the chip 26 to a bonding area R; each lead L1 is coupled to other external circuit by attached conductive structure (e.g., anisotropic conductive film, ACF) in the bonding area R. Because the lead L1 is separated from the boundary 28 by the distance d, the bonding area R locates inside the predetermined range 30 with the distance d separated from the boundary 28.

As each lead L1 of the integrated circuit 22 does not reach nor cross the boundary 28, each lead L1 will not contact the punch head of the puncher when the integrated circuit 22 is punched off from the base 24, and therefore no conductive residue will be left on the puncher. Accordingly, impact of lead residue for the integrated circuit 22 can be avoided; time and cost for punch process is also reduced since there in no need to frequently clean residue left on the puncher.

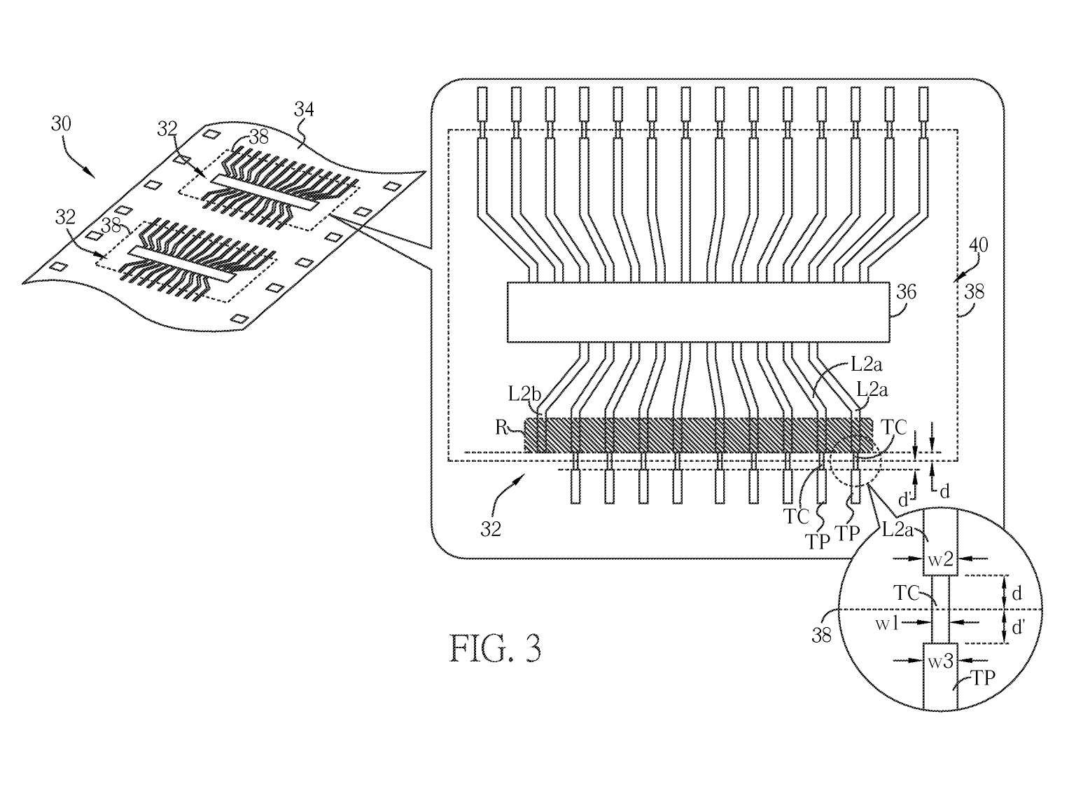

Please refer to FIG. 3 illustrating a semiconductor device 30 according to another embodiment of the invention. Similar to the semiconductor device 20, the semiconductor device 30 can also be a semiconductor device of chip on film package. The semiconductor device 30 includes multiple integrated circuit 32 formed on a base 34, e.g., a flexible film base.

Each integrated circuit 32 of the semiconductor device 30 includes a chip 36 and multiple leads L2a and L2b; a boundary (e.g., a cut line of punch) 38 defines a range 40 where the integrated circuit 32 locates, the boundary 38 can be a cut line of punch. The chip 36, the leads L2a and L2b are set inside the range 40, each of the leads L2a and L2b is coupled (connected) to the chip 36, and extends from the chip 36 toward the boundary 38 to reach the bonding area R, so the chip 36 can be coupled to other external circuit(s) (e.g., other chip(s), integrated circuit(s) and/or circuit board(s), not shown) via the leads L2a and L2b for exchanging signal/data and draining operation power.

Similar to the embodiment of FIG. 2, in each integrated circuit 32 of the semiconductor device 30, each of the leads L2a and L2b is separated from the boundary 38 by a predetermined distance d and therefore keeps away from the boundary 38. Furthermore, for each integrated circuit 32, multiple extension segments TC and external segments TP are formed on the base 34. Each of the external segments TP is set outside the range 40 and is separated from the boundary 38 by a predetermined distance d′; the distances d and d′ can be the same or different. Each of the extension segments TC extends across the boundary 38 with two terminals located at different sides of the boundary 38; one of the two terminals is coupled/connected to a lead L2a, and the other of the two terminals is coupled/connected to an external segment TP; for example, each of the external segments TP, each of the extension segments TC and each of the leads L2a can be formed on a same conductive layer of the base 34. Therefore, each external segment TP can be coupled to a corresponding lead L2a through bridging of a corresponding extension segment TC, and the chip 36 can also be coupled to other external circuit(s) through each of the external segments TP.

For example, a test pad can be set on the external segment TP; when the semiconductor device 30 is manufactured but each integrated circuit 32 is not punched off, a tester can be coupled to the external segments TP of each integrated circuit 32 via probes for testing functions of the integrated circuit 32 by signal/data exchange. After the test, the integrated circuit 32 can be punched off along the boundary 38, and the external segments TP and portions of the extension segments TP are cut off the integrated circuit 32.

As shown in FIG. 3, to reduce conductive residue left on the puncher, a width w1 (a cross-section dimension along the boundary 38) of the extension segment TC can be less than a width w2 of the lead L2a; the width w1 can also be less than a width w3 of the external segment TP. When the puncher punches the integrated circuit 32 off the base 34 along the boundary 38, because the puncher only cuts across the narrower extension segments TC, conductive residue left on the puncher can be reduced.

In the embodiment of FIG. 3, test of each integrated circuit 32 can be performed through corresponding external segments TP. In the embodiment of FIG. 2, test of each integrated circuit 22 can be performed through the leads L1; that is, probes of the tester are coupled to the leads L1 to test functions of each integrated circuit 22 by exchanging data/signal with the integrated circuit 22.

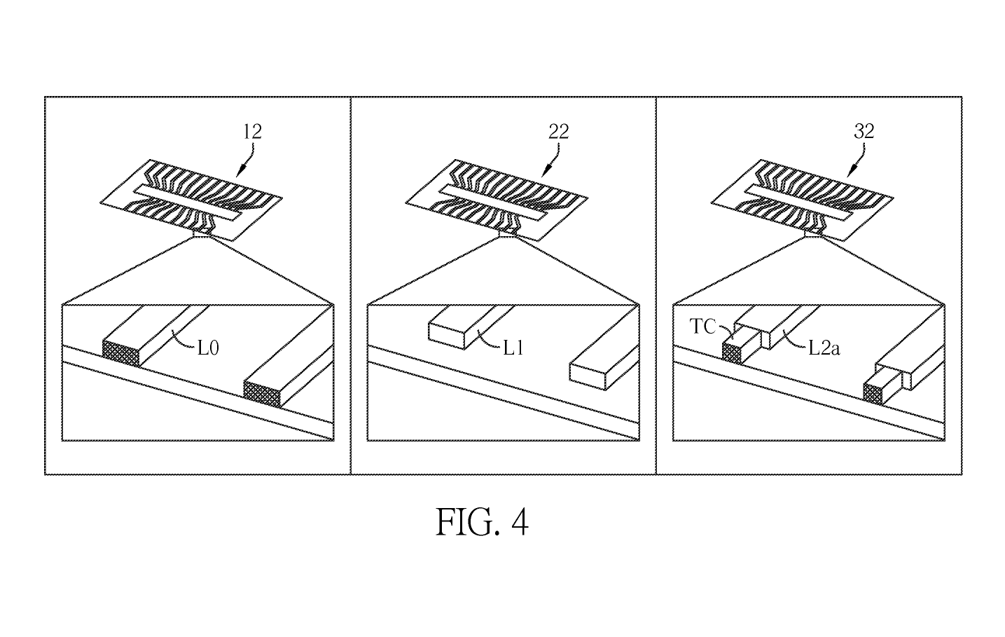

Please refer to FIG. 4 illustrating structures near boundaries of the integrated circuits 12, 22 and 32 (please also refer to FIG. 1 to FIG. 3). As shown in FIG. 4, the lead L0 of the integrated circuit 12 has largest cross-section dimensions across its boundary (cut line), so it leaves most amount of residue on the puncher. Comparatively, in the integrated circuit 32 of the invention, since only narrower extension segments TC extend to the boundary, the conductive cross-section dimensions across the boundary is reduced with effectively lessened residue on the puncher. Furthermore, each lead L1 of the integrated circuit 22 does not reach the boundary to avoid conductive residue of puncher.

To sum up, comparing to prior art, the invention effectively reduces or avoid conductive residue left on puncher, not only erroneous short circuit of integrated circuits owing to conductive residue can be prevented, but also efficiency of punch process can be increased.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor device comprising:
a base, and
at least an integrated circuit formed on the base, each integrated circuit comprising:
a chip set interior to a predetermined range of the base; the predetermined range having a boundary; and
a plurality of leads set interior to the predetermined range, each lead extending toward the boundary with a predetermined distance from the boundary.

2. The semiconductor device as claimed in claim 1, wherein in each integrated circuit, the plurality of leads extend from the chip to a bonding area which is inside the predetermined range with the predetermined distance away from the boundary.

3. The semiconductor device as claimed in claim 1 further comprising:
a plurality of extension segments corresponding to each integrated circuit, each of the extension segments extending across the boundary and being coupled to one of the plurality of leads in the corresponding integrated circuit, and a width of each of the extension segments is less than a width of each of the leads.

4. The semiconductor device as claimed in claim 3 further comprising:
a plurality of external segments corresponding to each integrated circuit; each of the external segments set exterior to the predetermined range of the corresponding integrated circuit and being coupled to one of the extension segments.

5. The semiconductor device as claimed in claim 4, wherein the plurality of lead, the plurality of extension segments and the plurality of the external segments are formed on a same conductive layer.

6. The semiconductor device as claimed in claim 1, wherein the base is a film base.

7. The semiconductor device as claimed in claim 1, wherein the boundary of each integrated circuit is a cut line of punch.
